(19) United States
(12) Patent Application Publication
(10) Pub. No.: US 2025/0149460 A1
(43) Pub. Date: May 8, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: CHOONGBIN YIM, Suwon-si (KR)

(21) Appl. No.: 18/663,234

(22) Filed: May 14, 2024

(30) Foreign Application Priority Data
Nov. 8, 2023 (KR) 10-2023-0153959

(51) Int. Cl. H01L 23/538; H01L 21/48; H01L 23/00; H01L 23/48; H01L 25/16; H10B 80/00

(52) U.S. Cl. CPC H01L 23/5389; H01L 21/4846; H01L 23/481; H01L 23/5381; H01L 23/5386; H01L 25/16; H10B 80/00; H01L 24/08; H01L 24/16; H01L 2224/08235; H01L 2224/16227; H01L 2224/16238; H01L 2224/16258; H01L 2224/16268; H01L 2924/19011

(57) ABSTRACT

A semiconductor package may include a first redistribution structure, a first semiconductor die on the first redistribution structure, a second semiconductor die on the front side redistribution structure and side-by-side with the first semiconductor die, a substrate on the front side redistribution structure and surrounding each of the first semiconductor die and the second semiconductor die, a bridge die on the substrate, a second redistribution structure on the substrate and around the bridge die, a third semiconductor die on the second redistribution structure and on the bridge die, and a fourth semiconductor die on the second redistribution structure and on the bridge die.

### CROSS-REFERENCE TO RELATED APPLICATION

This application claims priority to and the benefit of Korean Patent Application No. 10-2023-0153959 filed in the Korean Intellectual Property Office on Nov. 8, 2023, the entire contents of which are incorporated herein by reference.

### BACKGROUND OF THE INVENTION

### (a) Field of the Invention

The present disclosure relates to a semiconductor package and a method for manufacturing the same.

### (b) Description of the Related Art

The semiconductor industry seeks to increase integration density so that more passive or active devices can be integrated within a given area. Among them, the development of technology for miniaturizing a circuit line width of a front-end semiconductor process gradually faced limitations, and accordingly, the semiconductor industry tends to supplement limitations of the front-end semiconductor process by developing semiconductor package techniques capable of having high integration densities. According to this trend, package on package (PoP) technology has been developed, positioning a plurality of semiconductor dies side by side on a front side redistribution layer (FRDL) structure and a memory semiconductor die on a back side redistribution layer (BRDL) structure, and connecting the FRDL structure to the BRDL structure with conductive posts.

In the package-on-package technology, semiconductor chips on the front side redistribution structure and memory chips on the back side redistribution structure are electrically connected to each other through conductive posts. This results in a long electrical path from the semiconductor chips on the front side redistribution structure to the memory chip on the back side redistribution structure, which increases the size of the semiconductor package, and this may make it difficult to implement a high-performance semiconductor package.

Additionally, in package-on-package technology, the same processes such as exposure, development, etching, and deposition must be performed repeatedly to form a conductive post. Therefore, the process of forming a conductive post increases turnaround time (TAT) and the number of steps in the process is increased, causing a decrease in yield.

Therefore, a new semiconductor package technology is being developed in view of the problems of the conventional semiconductor package technology.

### SUMMARY OF THE INVENTION

A front side redistribution structure and a back side redistribution structure may be electrically connected by using an embedded trace substrate (ETS) instead of a conductive post.

A front side redistribution structure and a back side redistribution structure may be electrically connected by disposing through-silicon vias (TSV) within semiconductor dies on a front side redistribution structure.

A high bandwidth memory (HBM) and a semiconductor die disposed side-by-side with the high bandwidth memory (HBM) on the back side redistribution structure may be electrically interconnected by inserting a bridge die into a back side redistribution structure.

Surface-mount devices (SMD) may be mounted on an upper surface of the high bandwidth memory (HBM) on the back side redistribution structure.

A semiconductor package may include a first redistribution structure, a first semiconductor die on the first redistribution structure, a second semiconductor die on the first redistribution structure and side-by-side with the first semiconductor die, a substrate on the first redistribution structure and surrounding each of the first semiconductor die and the second semiconductor die, a bridge die on the substrate, a second redistribution structure on the substrate and around the bridge die, a third semiconductor die on the second redistribution structure and on the bridge die, and a fourth semiconductor die on the second redistribution structure and on the bridge die.

A semiconductor package may include a first redistribution structure, a first semiconductor die on the first redistribution structure, a second semiconductor die on the first redistribution structure and side-by-side with the first semiconductor die, a substrate on the first redistribution structure and surrounding each of the first semiconductor die and the second semiconductor die, a first molding material surrounding the first semiconductor die and the second semiconductor die, on the first redistribution structure, a bridge die on the substrate, a second redistribution structure on the substrate and around the bridge die, a third semiconductor die on the second redistribution structure and on the bridge die, a fourth semiconductor die on the second redistribution structure and on the bridge die, a second molding material surrounding the third semiconductor die and the fourth semiconductor die, on the second redistribution structure, and a surface-mount device (SMD) disposed on the third semiconductor die.

A manufacturing method of a semiconductor package may include forming a first redistribution structure, bonding a substrate including a first through opening and a second through opening on the first redistribution structure, mounting a first semiconductor die on the first redistribution structure and within the first through opening, and mounting a second semiconductor die on the first redistribution structure and within the second through opening, forming a second redistribution structure on the first semiconductor die, the second semiconductor die, and the substrate, mounting a bridge die within the second redistribution structure, and mounting a third semiconductor die and a fourth semiconductor die on the second redistribution structure and on the bridge die.

By using an ETS instead of the conductive post, a front side redistribution structure and a back side redistribution structure may be electrically connected such that a length of the electrical path between the front side redistribution structure and the back side redistribution structure may be reduced. In addition, since the process of manufacturing conductive posts in the semiconductor package may be removed, the turnaround time may be decreased, and yield may be improved.

By disposing a through-silicon vias TSV within semiconductor dies on a front side redistribution structure, a front side redistribution structure and a back side redistribution structure may be electrically connected. Accordingly, since the signals and electric power may be transferred rapidly and efficiently using through-silicon vias TSV, a high-performance semiconductor package including a high bandwidth memory (HBM) may be implemented.

By inserting a bridge die into a back side redistribution structure, a high bandwidth memory (HBM) and a semiconductor die disposed side-by-side with the high bandwidth memory (HBM) on the back side redistribution structure may be electrically connected such that a length of the electrical path between a high bandwidth memory (HBM) and a semiconductor die may be reduced.

Surface-mount devices (SMD) may be mounted on the upper surface of the high bandwidth memory (HBM) on the back side redistribution structure. Accordingly, electric characteristics of a semiconductor package may be maximized.

### BRIEF DESCRIPTION OF THE DRAWINGS

FIG. 1 is a cross-sectional view of a semiconductor package of an embodiment.

FIG. 2 is a top plan view of a semiconductor package of an embodiment.

FIG. 3 to FIG. 18 are cross-sectional views of a manufacturing method of a semiconductor package of an embodiment of FIG. 1.

### DETAILED DESCRIPTION OF THE EMBODIMENTS

Hereinafter, embodiments of the disclosure will be described in detail with reference to the accompanying drawings. The disclosure may be implemented in various forms, and may not necessarily be limited to embodiments expressly described herein.

The drawings and description are to be regarded as illustrative in nature and not restrictive. Like reference numerals designate like elements throughout the specification.

Further, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package 100 and a method for manufacturing the semiconductor package 100, of an embodiment, will be described with reference to drawings.

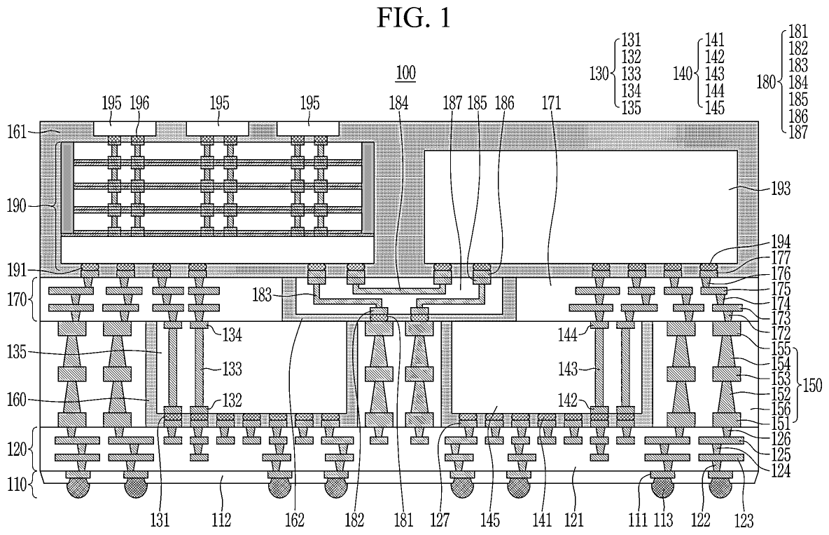

FIG. 1 is a cross-sectional view of the semiconductor package 100 of an embodiment.

Referring to FIG. 1, the semiconductor package 100 may include an external connection structure 110, a front side redistribution structure (e.g., first redistribution structure) 120, a first semiconductor die 130, a second semiconductor die 140, a substrate 150, a first molding material 160, a back side redistribution structure (e.g., second redistribution structure) 170, a bridge die 180, a third molding material 162, a third semiconductor die 190, a fourth semiconductor die 193, a surface-mount device (SMD) 195, and a second molding material 161. In an embodiment, the semiconductor package 100 may include a package-on-package (PoP). In an embodiment, the semiconductor package 100 may include a fan-out wafer level package (FOWLP) or a fan-out panel level package (FOPLP).

The external connection structure 110 is disposed on a bottom surface of a front side redistribution structure 120. The external connection structure 110 includes conductive pads 111, an insulation member 112, and external connection members 113. A conductive pad 111 electrically connects a first redistribution via 122 of the front side redistribution structure 120 to the external connection member 113. The insulation member 112 includes a plurality of openings for soldering. The insulation member 112 prevents the external connection members 113 from being short-circuited to each other. The external connection member 113 electrically connects the semiconductor package 100 to an external device (not shown).

The front side redistribution structure 120 includes a first dielectric material layer 121, first redistribution vias 122 within the first dielectric material layer 121, first redistribution lines 123, second redistribution vias 124, second redistribution lines 125 and third redistribution vias 126, and first bonding pads 127 on the first dielectric material layer 121. In another embodiment, the front side redistribution structure 120 including fewer or greater numbers of redistribution lines, redistribution vias, and bonding pads is included within the scope of the present disclosure.

The first dielectric material layer 121 may protect and insulate the first redistribution vias 122, the first redistribution lines 123, the second redistribution vias 124, the second redistribution lines 125, and the third redistribution vias 126. The first semiconductor die 130, the second semiconductor die 140, and the substrate 150 are disposed on an upper surface of the first dielectric material layer 121. The external connection structure 110 is disposed on a bottom surface of the first dielectric material layer 121.

The first redistribution via 122 is disposed between the first redistribution line 123 and the conductive pad 111. The first redistribution via 122 electrically connects the first redistribution line 123 to the external connection member 113 connected to the conductive pad 111, in a vertical direction. The first redistribution line 123 is disposed between the first redistribution via 122 and a second redistribution via 124. The first redistribution line 123 electrically connects the first redistribution via 122 to the second redistribution via 124 in a horizontal direction. The second redistribution via 124 is disposed between the first redistribution line 123 and a second redistribution line 125. The second redistribution via 124 electrically connects the second redistribution line 125 to the first redistribution line 123, in the vertical direction. The second redistribution line 125 is disposed between the second redistribution via 124 and a third redistribution via 126. The second redistribution line 125 electrically connects the second redistribution via 124 to the third redistribution via 126 in the horizontal direction.

The third redistribution via 126 is disposed between the first bonding pad 127 and the second redistribution line 125, and between a first wire layer 151 and the second redistribution line 125 of the substrate 150. The third redistribution via 126 electrically connects the first bonding pad 127 to the second redistribution line 125, and the first wire layer 151 of the substrate 150 to the second redistribution line 125, in the vertical direction.

The first bonding pad 127 is disposed between the third redistribution via 126 and a first connection member 131 of the first semiconductor die 130, and between the third redistribution via 126 and a second connection member 141 of the second semiconductor die 140. The first bonding pad 127 electrically connects the first connection member 131 of the first semiconductor die 130 to the third redistribution via 126, and the second connection member 141 of the second semiconductor die 140 to the third redistribution via 126, in the vertical direction.

The first semiconductor die 130 is disposed on the front side redistribution structure 120. The first semiconductor die 130 is disposed side by side with the second semiconductor die 140. The first semiconductor die 130 may include first connection members 131, first lower connection pads 132, first through-silicon vias (TSV) 133, first upper connection pads 134, and a first die base 135. In an embodiment, the first semiconductor die 130 may include an application processor (AP). In an embodiment, the first semiconductor die 130 may include at least one of a central processing unit (CPU) and a graphics processing unit (GPU).

The first connection member 131 is disposed between the first lower connection pad 132 and the first bonding pad 127 of the front side redistribution structure 120, and between the first bonding pad 127 of the front side redistribution structure 120 and a wire of the first die base 135. The first connection member 131 electrically connects the first lower connection pad 132 to the first bonding pad 127 of the front side redistribution structure 120, and the wire of the first die base 135 to the first bonding pad 127 of the front side redistribution structure 120. In an embodiment, the first connection members 131 may be formed of or include micro-bumps or solder balls. In an embodiment, the first connection members 131 may include at least one of tin, silver, lead, nickel, copper or an alloy thereof.

The first lower connection pad 132 is disposed between the first through-silicon via (TSV) 133 and the first connection member 131. The first lower connection pad 132 electrically connects the first through-silicon via (TSV) 133 to the first connection member 131.

The first through-silicon via (TSV) 133 is disposed between the first lower connection pad 132 and a first upper connection pad 134. The first through-silicon via (TSV) 133 electrically connects the first upper connection pad 134 to the first lower connection pad 132. According to the present disclosure, by disposing first through-silicon vias (TSV) 133 within the first semiconductor die 130, an additional electrical path between a front side redistribution structure and a back side redistribution structure may be secured. Accordingly, since signals and electric power may be transferred rapidly and efficiently through the first through-silicon vias (TSV) 133, a high-performance semiconductor package including a high bandwidth memory (HBM) may be implemented.

The first upper connection pad 134 is disposed between a fourth redistribution via 172 of a back side redistribution structure 170 and the first through-silicon via (TSV) 133. The first upper connection pad 134 electrically connects the fourth redistribution via 172 of the back side redistribution structure 170 to the first through-silicon via (TSV) 133.

In an embodiment, the first lower connection pad 132 and the first upper connection pad 134 may be formed of or include at least one of copper, aluminum, silver, tin, gold, nickel, lead, titanium, and an alloy thereof, respectively. In an embodiment, the first through-silicon via (TSV) 133 may be formed of or include at least one of tungsten, aluminum, copper and an alloy thereof.

The second semiconductor die 140 is disposed on the front side redistribution structure 120. The second semiconductor die 140 is disposed side by side with the first semiconductor die 130. The second semiconductor die 140 may include second connection members 141, second lower connection pads 142, second through-silicon vias (TSV) 143, second upper connection pads 144, and a second die base 145. In an embodiment, the second semiconductor die 140 may include a communication processor (CP). In an embodiment, the second semiconductor die 140 may include at least one of a central processing unit (CPU) and a graphics processing unit (GPU).

The second connection member 141 is disposed between the second lower connection pad 142 and the first bonding pad 127 of the front side redistribution structure 120, and between the first bonding pad 127 of the front side redistribution structure 120 and a wire of the second die base 145. The second connection member 141 electrically connects the second lower connection pad 142 to the first bonding pad 127 of the front side redistribution structure 120, and the wire of the second die base 145 to the first bonding pad 127 of the front side redistribution structure 120. In an embodiment, the second connection members 141 may be formed of or include micro-bumps or solder balls. In an embodiment, the second connection members 141 may include at least one of tin, silver, lead, nickel, copper or an alloy thereof.

The second lower connection pad 142 is disposed between the second through-silicon via (TSV) 143 and the second connection member 141. The second lower connection pad 142 electrically connects the second through-silicon via (TSV) 143 to the second connection member 141.

The second through-silicon via (TSV) 143 is disposed between the second lower connection pad 142 and a second upper connection pad 144. The second through-silicon via (TSV) 143 electrically connects the second upper connection pad 144 to the second lower connection pad 142. According to the present disclosure, by disposing the second through-silicon vias (TSV) 143 within the second semiconductor die 140, an additional electrical path between a front side redistribution structure and a back side redistribution structure may be secured. Accordingly, since signals and electric power may be transferred rapidly and efficiently through the second through-silicon vias (TSV) 143, a high-performance semiconductor package including a high bandwidth memory (HBM) may be implemented.

The second upper connection pad 144 is disposed between the fourth redistribution via 172 of the back side redistribution structure 170 and the second through-silicon via (TSV) 143. The second upper connection pad 144 electrically connects the fourth redistribution via 172 of the back side redistribution structure 170 to the second through-silicon via (TSV) 143.

In an embodiment, the second lower connection pad 142 and the second upper connection pad 144 may be formed of or include at least one of copper, aluminum, silver, tin, gold, nickel, lead, titanium, and an alloy thereof, respectively. In an embodiment, the second through-silicon via (TSV) 143 may be formed of or include at least one of tungsten, aluminum, copper and an alloy thereof.

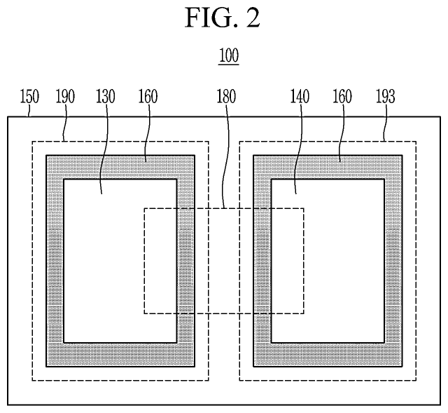

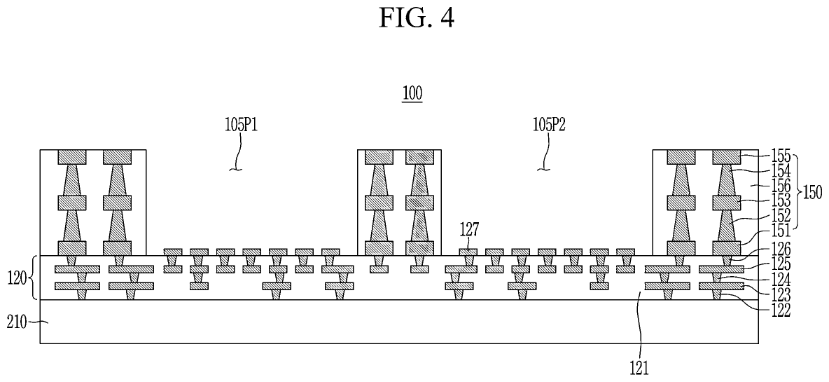

The substrate 150 is disposed on the front side redistribution structure 120. The substrate 150 is disposed around the first semiconductor die 130 and the second semiconductor die 140. The substrate 150 is disposed to surround a side surface of the first semiconductor die 130 and a side surface of the second semiconductor die 140 (see, e.g., FIG. 2). For example, the substrate 150 may surround an outside of the first semiconductor die 130 and the second semiconductor die 140. For example, the substrate 150 may be formed between the first semiconductor die 130 and the second semiconductor die 140. For example, the substrate 150 may be formed at the same vertical level as the first semiconductor die 130 and the second semiconductor die 140. The substrate 150 includes a first through opening 150P1 in which the first semiconductor die 130 is disposed and a second through opening 150P2 in which the second semiconductor die 140 is disposed (see, e.g., FIG. 4). The substrate 150 may include the first wire layer 151, a first via 152, a second wire layer 153, a second via 154, a third wire layer 155 and an insulation layer 156. The substrate 150 electrically connects the back side redistribution structure 170 to the front side redistribution structure 120. In an embodiment, the substrate 150 may include a printed circuit board (PCB). In an embodiment, the substrate 150 may include an embedded trace substrate (ETS).

The first wire layer 151 is disposed between the first via 152 and the third redistribution via 126 of the front side redistribution structure 120. The first wire layer 151 electrically connects the first via 152 to the third redistribution via 126 of the front side redistribution structure 120, in the horizontal direction. The first via 152 is disposed between the first wire layer 151 and the second wire layer 153. The first via 152 electrically connects the second wire layer 153 to the first wire layer 151, in the vertical direction. The second wire layer 153 is disposed between the first via 152 and the second via 154. The second wire layer 153 electrically connects the second via 154 to the first via 152, in the horizontal direction. The second via 154 is disposed between the second wire layer 153 and the third wire layer 155. The second via 154 electrically connects the third wire layer 155 to the second wire layer 153, in the vertical direction. The third wire layer 155 is disposed between the fourth redistribution via 172 of the back side redistribution structure 170 and the second via 154. The third wire layer 155 electrically connects the fourth redistribution via 172 of the back side redistribution structure 170 to the second via 154, in the horizontal direction. The insulation layer 156 may surround and protect the first wire layer 151, the first via 152, the second wire layer 153, the second via 154, and the third wire layer 155. In the embodiment of FIG. 1, the substrate 150 includes two layers of vias, however in another embodiment, the substrate 150 may include multiple layers of three or more layers. In another embodiment, a substrate 150 that includes fewer or greater numbers of wiring layer, and vias are within the scope of the present disclosure.

In an embodiment, the first via 152 and the second via 154 may include a truncated circular cone shape having a narrowing diameter from a bottom surface to an upper surface. In an embodiment, the first via 152 and the second via 154 may include a truncated circular cone shape having a narrowing diameter from an upper surface to a bottom surface. In an embodiment, the first via 152 and the second via 154 may include a cylindrical shape having a constant diameter from an upper surface to a bottom surface.

In an embodiment, the insulation layer 156 may be formed of or include a thermosetting resin such as an epoxy resin, a thermoplastic resin such as polyimide, or a mixture of such a resin and an inorganic filler. In an embodiment, the insulating layer 156 may include a resin impregnated into a core material such as glass fiber (or glass cloth, glass fabric) with an inorganic filler. In an embodiment, the insulation layer 156 may include a prepreg, Ajinomoto Build-up Film (ABF), FR-4, and/or bismaleimide triazine (BT). In an embodiment, the insulation layer 156 may include a photoimageable dielectric (photosensitive dielectric, PID). In an embodiment, the first wire layer 151, the second wire layer 153, and the third wire layer 155 may be formed of or include at least one of copper, aluminum, silver, tin, gold, nickel, lead, titanium, and an alloy thereof, respectively. In an embodiment, the first via 152 and the second via 154 may be formed of or include at least one of copper, aluminum, silver, tin, gold, nickel, lead, titanium, and an alloy thereof, respectively.

According to the present disclosure, the front side redistribution structure 120 and the back side redistribution structure 170 may be electrically connected by using the substrate 150 (e.g., ETS) instead of conductive posts conventionally disposed between the front side redistribution structure and the back side redistribution structure. Accordingly, the length of the electrical path between the front side redistribution structure 120 and the back side redistribution structure 170 may be reduced. In addition, since the process of manufacturing conductive posts in the semiconductor package 100 may be removed, the turnaround time (TAT) may be decreased, and yield may be improved.

The first molding material 160 is disposed on the front side redistribution structure 120, and molds (e.g., surrounds) the first semiconductor die 130 and the second semiconductor die 140 within the substrate 150.

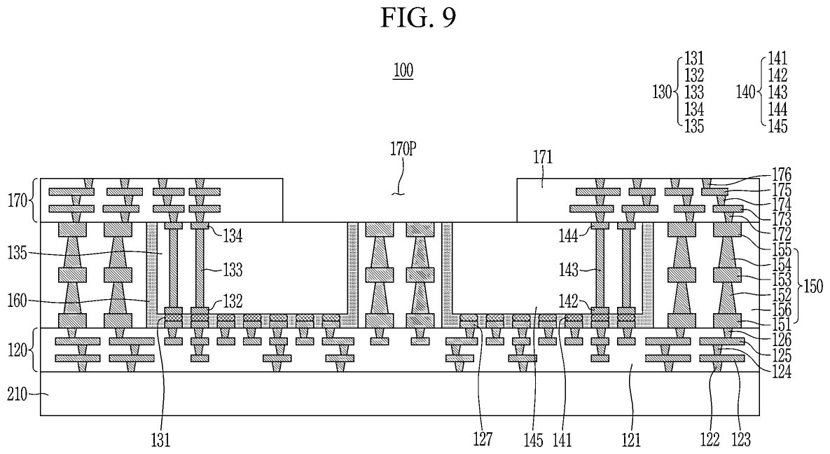

The back side redistribution structure 170 is disposed on the first semiconductor die 130, the second semiconductor die 140, the substrate 150, and the first molding material 160. The back side redistribution structure 170 includes a third through opening 170P in which the bridge die 180 is disposed (see, e.g., FIG. 9). The back side redistribution structure 170 includes a second dielectric material layer 171, fourth redistribution vias 172, third redistribution lines 173, fifth redistribution vias 174, fourth redistribution lines 175, and sixth redistribution vias 176 within the second dielectric material layer 171, and second bonding pads 177 of the second dielectric material layer 171. In another embodiment, the back side redistribution structure 170 including fewer or greater numbers of redistribution lines, redistribution vias, and bonding pads is included within the scope of the present disclosure.

The second dielectric material layer 171 may protect and insulate the fourth redistribution vias 172, the third redistribution lines 173, the fifth redistribution vias 174, the fourth redistribution lines 175, and the sixth redistribution vias 176. The third semiconductor die 190 and the fourth semiconductor die 193 are disposed on an upper surface of the second dielectric material layer 171. The first semiconductor die 130, the second semiconductor die 140, the substrate 150, and the first molding material 160 are disposed on a bottom surface of the second dielectric material layer 171.

The fourth redistribution via 172 is disposed between the third redistribution line 173 and the third wire layer 155 of the substrate 150, between the third redistribution line 173 and the first upper connection pad 134 of the first semiconductor die 130, and between the third redistribution line 173 and the second upper connection pad 144 of the second semiconductor die 140. The fourth redistribution via 172 electrically connects the third redistribution line 173 to the third wire layer 155 of the substrate 150, the third redistribution line 173 to the first upper connection pad 134 of the first semiconductor die 130, and the third redistribution line 173 to the second upper connection pad 144 of the second semiconductor die 140, in the vertical direction. The third redistribution line 173 is disposed between the fourth redistribution via 172 and a fifth redistribution via 174. The third redistribution line 173 electrically connects the fourth redistribution via 172 to the fifth redistribution via 174, in the horizontal direction. The fifth redistribution via 174 is disposed between the third redistribution line 173 and a fourth redistribution line 175. The fifth redistribution via 174 electrically connects the fourth redistribution line 175 to the third redistribution line 173, in the vertical direction. The fourth redistribution line 175 is disposed between the fifth redistribution via 174 and a sixth redistribution via 176. The fourth redistribution line 175 electrically connects the fifth redistribution via 174 to the sixth redistribution via 176, in the horizontal direction. The sixth redistribution via 176 is disposed between the fourth redistribution line 175 and a second bonding pad 177. The sixth redistribution via 176 electrically connects the second bonding pad 177 to the fourth redistribution line 175, in the vertical direction. The second bonding pad 177 is disposed between the sixth redistribution via 176 and a third connection member 191 of the third semiconductor die 190, and between the sixth redistribution via 176 and a fourth connection member 194 of the fourth semiconductor die 193. The second bonding pad 177 electrically connects the third connection member 191 of the third semiconductor die 190 to the sixth redistribution via 176, and the fourth connection member 194 of the fourth semiconductor die 193 to the sixth redistribution via 176.

The bridge die 180 is disposed within the third through opening 170P of the back side redistribution structure 170. The bridge die 180 electrically connects the third semiconductor die 190 to the fourth semiconductor die 193 in the horizontal direction, electrically connects the third semiconductor die 190 to the front side redistribution structure 120 through the substrate 150 in the vertical direction, and electrically connects the fourth semiconductor die 193 the front side redistribution structure 120 through the substrate 150 in the vertical direction. The bridge die 180 may be electrically insulated from the back side redistribution structure 170 by third molding material 162 to be described below.

The bridge die 180 may include connection members 181, third lower connection pads 182, first wire lines 183, second wire lines 184, third upper connection pads 185, third bonding pads 186 and a bridge base 187. In an embodiment, the bridge die 180 may include a silicon bridge. The first wire lines 183 included in the bridge die 180 rapidly move data in the vertical direction, and the second wire lines 184 rapidly move data in the horizontal direction. In one or more embodiments, the bridge die may not include any active circuit elements. In one or more embodiments, the bridge die may be formed of or include undoped silicon. Therefore, the signal transmission path between the third semiconductor die 190, the fourth semiconductor die 193, and the front side redistribution structure 120 (via the substrate 150) may be optimized, and accordingly, by decreasing power consumption, performance of the semiconductor package may be improved.

A connection member 181 is disposed between the third lower connection pad 182 and the third wire layer 155 of the substrate 150. The connection member 181 electrically connects the third lower connection pad 182 to the third wire layer 155 of the substrate 150. In an embodiment, the connection members 181 may be formed of or include micro-bumps or solder balls. In an embodiment, the connection members 181 may include at least one of tin, silver, lead, nickel, copper or an alloy thereof.

The third lower connection pad 182 is disposed between the connection member 181 and a first wire line 183, and electrically connects the first wire line 183 to the connection member 181.

The first wire line 183 is disposed between the third lower connection pad 182 and a third upper connection pad 185, and in the vertical direction, electrically connects the third semiconductor die 190 connected to the third upper connection pad 185 to the third lower connection pad 182, and the fourth semiconductor die 193 connected to the third upper connection pad 185 to the third lower connection pad 182.

A second wire line 184 is disposed between the third upper connection pads 185, and in the horizontal direction, electrically interconnects the third semiconductor die 190 connected to the third upper connection pad 185 to the fourth semiconductor die 193 connected to the third upper connection pad 185.

The third upper connection pad 185 is disposed between the first wire line 183 and a third bonding pad 186 and between the second wire line 184 and the third bonding pad 186, and electrically connects the third bonding pad 186 to the first wire line 183 and the third bonding pad 186 to the second wire line 184.

The third bonding pad 186 is disposed between the third upper connection pad 185 and a third connection member 191 of the third semiconductor die 190, and between the third upper connection pad 185 and a fourth connection member 194 of the fourth semiconductor die 193. The third bonding pad 186 electrically connects the third connection member 191 of the third semiconductor die 190 to the third upper connection pad 185, and the fourth connection member 194 of the fourth semiconductor die 193 to the third upper connection pad 185.

The bridge base 187 may protect and insulate the third lower connection pads 182, the first wire lines 183, the second wire lines 184, and the third upper connection pads 185. Side surfaces and a bottom surface of the bridge base 187 are molded (e.g., surrounded) by the third molding material 162, and its upper surface is molded (e.g., covered or defined) by the second molding material 161.

In an embodiment, the first wire line 183 and the second wire line 184 may be formed of or include at least one of tungsten, aluminum, copper and an alloy thereof, respectively. In an embodiment, a third lower connection pad 182, a third upper connection pad 185, and the third bonding pad 186 may be formed of or include at least one of copper, aluminum, silver, tin, gold, nickel, lead, titanium, and an alloy thereof, respectively. In an embodiment, the bridge base 187 may be formed of or include a silicon oxide.

The third molding material 162 is disposed on the first semiconductor die 130, the second semiconductor die 140, the substrate 150, and the first molding material 160, and molds (e.g., surrounds) the bridge die 180 within the back side redistribution structure 170.

The third semiconductor die 190 is disposed on the back side redistribution structure 170. In an embodiment, the third semiconductor die 190 may be a high bandwidth memory (HBM). The high bandwidth memory (HBM) is a high-performance 3D-stack dynamic random-access memory (DRAM). The high-bandwidth memory (HBM) is manufactured by vertically stacking memory dies by performing hybrid bonding or using micro-bumps to form a single memory stack. High-bandwidth memory (HBM) has multiple memory channels through a memory stack in which memory dies are vertically stacked, may simultaneously realize shorter latency and higher bandwidth than conventional DRAM products, and may reduce the total area occupied by individual DRAMs on a substrate, and therefore, it is advantageous in terms of high bandwidth compared to area and has the advantage of reducing power consumption.

The third semiconductor die 190 includes a buffer die and a plurality of memory dies stacked on the buffer die. The third semiconductor die 190 includes third connection members 191. The third connection member 191 is disposed on the second bonding pad 177 of the back side redistribution structure 170 and on the third bonding pad 186 of the bridge die 180. The third connection member 191 is electrically connected to the second bonding pad 177 of the back side redistribution structure 170, and to the third bonding pad 186 of the bridge die 180. In an embodiment, the third connection member 191 may be formed of or include micro-bumps or solder balls. In an embodiment, the third connection member 191 may include at least one of tin, silver, lead, nickel, copper or an alloy thereof.

The fourth semiconductor die 193 is disposed on the back side redistribution structure 170. In an embodiment, the fourth semiconductor die 193 may include a radio frequency IC (RFIC) chip, a display driver IC (DDI) chip, a sensor chip, or a power management IC (PMIC) chip. The fourth semiconductor die 193 includes fourth connection members 194. The fourth connection member 194 is disposed on the second bonding pad 177 of the back side redistribution structure 170 and on the third bonding pad 186 of the bridge die 180. The fourth connection member 194 is electrically connected to the second bonding pad 177 of the back side redistribution structure 170, and to the third bonding pad 186 of the bridge die 180. In an embodiment, the fourth connection member 194 may be formed of or include micro-bumps or solder balls. In an embodiment, the fourth connection member 194 may include at least one of tin, silver, lead, nickel, copper or an alloy thereof.

One or more surface-mount devices (SMD) 195 is disposed on the third semiconductor die 190. The surface-mount device (SMD) 195 is electrically connected to the third semiconductor die 190 by fifth connection members 196. In an embodiment, the surface-mount device (SMD) 195 may provide additional functionality or programming throughout the semiconductor package 100. In an embodiment, the surface-mount device (SMD) 195 may be formed of or include at least one of a resistor, an inductor, a capacitor, and a jumper. In an embodiment, the surface-mount device (SMD) 195 may include an integrated stack capacitor (ISC).

According to the present disclosure, by mounting the surface-mount devices (SMD) on the upper surface of the high bandwidth memory on the back side redistribution structure, electric characteristics of the semiconductor package may be maximized. In addition, since the surface-mount device (SMD) that was conventionally disposed side by side with external connection members under the substrate is modified to be disposed on an upper surface of the third semiconductor die 190 (e.g., the high bandwidth memory (HBM)), the number of external connection members that had to be reduced in order to secure the area on which the surface-mount device (SMD) is disposed may not need to be reduced, and the size of the semiconductor package may be reduced.

The second molding material 161 is disposed on the back side redistribution structure 170, and molds (e.g., surrounds) the third semiconductor die 190, the fourth semiconductor die 193, and one or more surface-mount devices (SMD) 195.

FIG. 2 is a top plan view of the semiconductor package 100 of an embodiment. In FIG. 2, an upper surface of the substrate 150 around the first semiconductor die 130, the second semiconductor die 140, and the first semiconductor die 130 and the second semiconductor die 140 is shown.

Referring to FIG. 1, FIG. 2 and FIG. 4, the first semiconductor die 130 is disposed within the first through opening 150P1 of the substrate 150. The second semiconductor die 140 is disposed within the second through opening 150P2 of the substrate 150. In FIG. 2, the bridge die 180, the third semiconductor die 190, and the fourth semiconductor die 193 disposed above the first semiconductor die 130, the second semiconductor die 140, and the substrate 150 are illustrated in dashed lines. Since the third semiconductor die 190 and the fourth semiconductor die 193 are disposed above the bridge die 180 and the substrate 150 is disposed below the bridge die 180, the bridge die 180 may electrically connect the third semiconductor die 190, the fourth semiconductor die 193, and the substrate 150 to each other.

In FIG. 2, it is illustrated that the one integrally formed substrate 150 surrounds the first semiconductor die 130 and the second semiconductor die 140, but it is not limited thereto, and a plurality of substrates 150 may surround the first semiconductor die 130 and the second semiconductor die 140, according to the present disclosure.

FIG. 1 and in FIG. 2, it is illustrated that the bridge die 180 electrically connects the third semiconductor die 190, the fourth semiconductor die 193, and the substrate 150 to each other, but it is not limited thereto, and the bridge die 180 may also be electrically connected to the first semiconductor die 130 and the second semiconductor die 140.

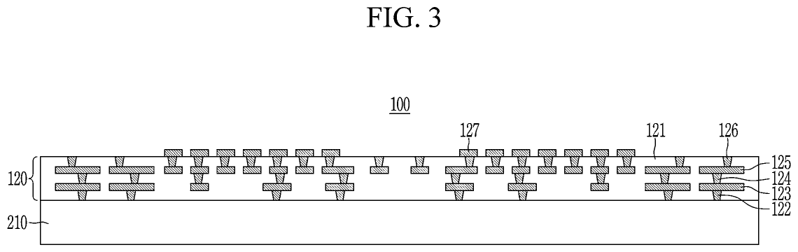

FIG. 3 a cross-sectional view showing the step of forming the front side redistribution structure 120 on a carrier 210.

Referring to FIG. 3, the front side redistribution structure 120 is formed on the carrier 210. First, the carrier 210 is provided. The carrier 210 may be formed of or include, for example, a silicon-based material such as glass or silicon oxide, an organic material, or another material such as aluminum oxide, any combination of these materials, and the like.

Then, the first dielectric material layer 121 is formed on the carrier 210. In an embodiment, the first dielectric material layer 121 may be formed of or include a photoimageable dielectric (photosensitive dielectric; PID) used in the redistribution layer process. A photoimageable dielectric is a material capable of forming a fine pattern by applying a photolithography process. As an embodiment, photoimageable dielectric (PID) may include polyimide-based photoactive polymer, novolac-based photoactive polymer, polybenzoxazole, silicone-based polymer, acrylate-based polymer, or epoxy-based polymer. In another embodiment, the first dielectric material layer 121 is formed of an inorganic dielectric material such as silicon nitride, silicon oxide, or the like. In an embodiment, the first dielectric material layer 121 may be formed by a CVD, ALD, or PECVD process.

After forming the first dielectric material layer 121, via holes may be formed by selectively etching the first dielectric material layer 121, and the first redistribution vias 122 are formed by filling the via holes with a conductive material.

Then, the first dielectric material layer 121 is additionally deposited on the first redistribution vias 122 and the first dielectric material layer 121, openings are formed by selectively etching the additionally deposited first dielectric material layer 121, and the first redistribution lines 123 are formed by filling the opening with a conductive material.

Then, the first dielectric material layer 121 is additionally deposited on the first redistribution lines 123 and the first dielectric material layer 121, the via holes are formed by selectively etching the additionally deposited first dielectric material layer 121, and the second redistribution vias 124 are formed by filling the via holes with a conductive material.

Then, the first dielectric material layer 121 is additionally deposited on the second redistribution vias 124 and the first dielectric material layer 121, openings are formed by selectively etching the additionally deposited first dielectric material layer 121, and the second redistribution lines 125 are formed by filling the opening with a conductive material.

Then, the first dielectric material layer 121 is additionally deposited on the second redistribution lines 125 and the first dielectric material layer 121, the via holes are formed by selectively etching the additionally deposited first dielectric material layer 121, and the third redistribution vias 126 are formed by filling the via holes with a conductive material.

Then, photoresist (not shown) is additionally deposited on the third redistribution vias 126 and the first dielectric material layer 121, a photoresist pattern including via holes is formed by selectively exposing and developing the photoresist, and the first bonding pads 127 are formed by filling the via holes with a conductive material.

In an embodiment, the first redistribution vias 122, the first redistribution lines 123, the second redistribution vias 124, the second redistribution lines 125, the third redistribution vias 126, and the first bonding pads 127 may be formed of or include at least one of copper, aluminum, tungsten, nickel, gold, tin, titanium, and an alloy thereof, respectively. In an embodiment, the first redistribution vias 122, the first redistribution lines 123, the second redistribution vias 124, the second redistribution lines 125, the third redistribution vias 126, and the first bonding pads 127 may be formed by performing a sputtering process, respectively. In another embodiment, each of the first redistribution vias 122, the first redistribution lines 123, the second redistribution vias 124, the second redistribution lines 125, the third redistribution vias 126, and the first bonding pads 127 may be formed by performing an electrolytic plating process after forming the seed metal layer, respectively.

FIG. 4 a cross-sectional view showing the step of bonding the substrate 150 on the front side redistribution structure 120.

Referring to FIG. 4, the substrate 150 is bonded on the front side redistribution structure 120 by performing a thermal compression (TC) process. The substrate 150 includes the first through opening 150P1 and the second through opening 150P2.

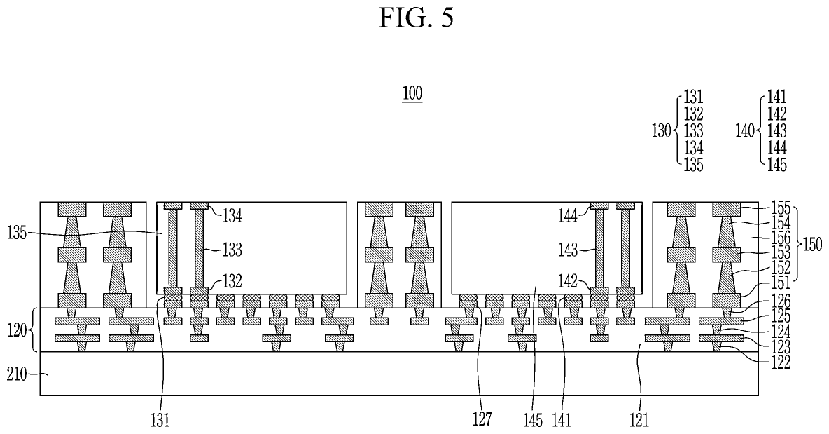

FIG. 5 a cross-sectional view showing the step of mounting the first semiconductor die 130 and the second semiconductor die 140 on the front side redistribution structure 120.

Referring to FIG. 5, the first semiconductor die 130 and the second semiconductor die 140 are mounted on the front side redistribution structure 120 through flip chip bonding. The first semiconductor die 130 is mounted within the first through opening 150P1 of the substrate 150, and the second semiconductor die 140 is mounted within the second through opening 150P2 of the substrate 150. The first semiconductor die 130 and the second semiconductor die 140 are disposed side by side and at the same level. The first connection members 131 of the first semiconductor die 130 are bonded to the first bonding pads 127 of the front side redistribution structure 120, so that the first semiconductor die 130 and the front side redistribution structure 120 are electrically connected to each other. The second connection members 141 of the second semiconductor die 140 are bonded to the first bonding pads 127 of the front side redistribution structure 120, so that the second semiconductor die 140 and the front side redistribution structure 120 are electrically connected to each other.

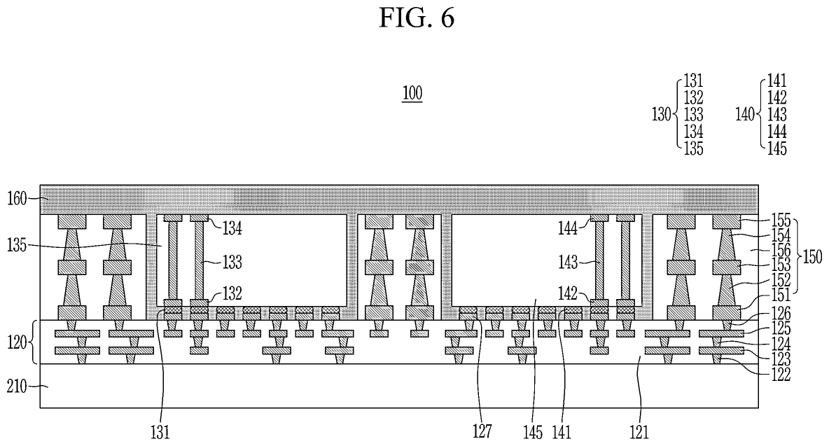

FIG. 6 is a cross-sectional view showing the step of molding the first semiconductor die 130 and the second semiconductor die 140 by the first molding material 160, on the front side redistribution structure 120.

Referring to FIG. 6, on the front side redistribution structure 120, the first semiconductor die 130 within the first through opening 150P1 of the substrate 150 and the second semiconductor die 140 within the second through opening 150P2 of the substrate 150 are molded (e.g., surrounded) by the first molding material 160. In an embodiment, the process of molding with the first molding material 160 may include a compression molding or transfer molding process. In an embodiment, the first molding material 160 may be formed of or include an epoxy molding compound EMC.

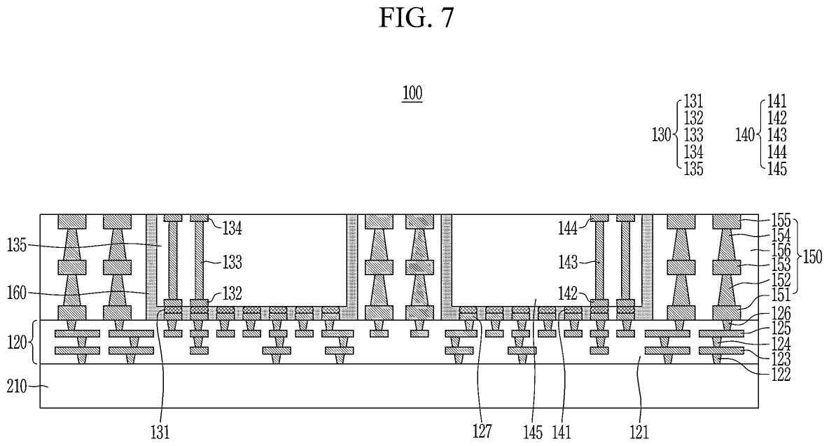

FIG. 7 a cross-sectional view showing the step of planarizing the first molding material 160.

Referring to FIG. 7, chemical mechanical polishing (CMP) may be performed in order to level an upper surface of the first molding material 160. The upper surface of the first molding material 160 may be planarized by applying the CMP process. After performing the CMP process, upper surfaces of the substrate 150, the first semiconductor die 130, and the second semiconductor die 140 are exposed.

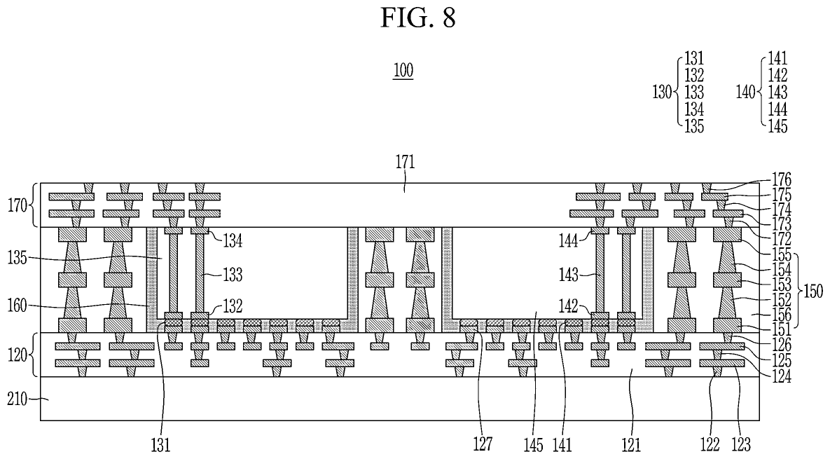

FIG. 8 is a cross-sectional view showing the step of forming the back side redistribution structure 170 on the first semiconductor die 130, the second semiconductor die 140, the substrate 150, and the first molding material 160.

Referring to FIG. 8, the back side redistribution structure 170 is formed on the first semiconductor die 130, the second semiconductor die 140, the substrate 150, and the first molding material 160.

First, the second dielectric material layer 171 is formed on the first semiconductor die 130, the second semiconductor die 140, the substrate 150, and the first molding material 160. In an embodiment, the second dielectric material layer 171 may be formed of or include a photoimageable dielectric (photosensitive dielectric; PID) used in the redistribution layer process. A photoimageable dielectric is a material capable of forming a fine pattern by applying a photolithography process. As an embodiment, photoimageable dielectric (PID) may include polyimide-based photoactive polymer, novolac-based photoactive polymer, polybenzoxazole, silicone-based polymer, acrylate-based polymer, or epoxy-based polymer. In another embodiment, the second dielectric material layer 171 is formed of an inorganic dielectric material such as silicon nitride, silicon oxide, or the like. In an embodiment, the second dielectric material layer 171 may be formed by a CVD, ALD, or PECVD process.

After forming the second dielectric material layer 171, via holes may be formed by selectively etching the second dielectric material layer 171, and the fourth redistribution vias 172 are formed by filling the via holes with a conductive material.

Then, the second dielectric material layer 171 is additionally deposited on the fourth redistribution vias 172 and the second dielectric material layer 171, openings are formed by selectively etching the additionally deposited second dielectric material layer 171, and the third redistribution lines 173 are formed by filling the opening with a conductive material.

Then, the second dielectric material layer 171 is additionally deposited on the third redistribution lines 173 and the second dielectric material layer 171, the via holes are formed by selectively etching the additionally deposited second dielectric material layer 171, and the fifth redistribution vias 174 are formed by filling the via holes with a conductive material.

Then, the second dielectric material layer 171 is additionally deposited on the fifth redistribution vias 174 and the second dielectric material layer 171, openings are formed by selectively etching the additionally deposited second dielectric material layer 171, and the fourth redistribution lines 175 are formed by filling the opening with a conductive material.

Then, the second dielectric material layer 171 is additionally deposited on the fourth redistribution lines 175 and the second dielectric material layer 171, the via holes are formed by selectively etching the additionally deposited second dielectric material layer 171, and the sixth redistribution vias 176 are formed by filling the via holes with a conductive material.

In an embodiment, the fourth redistribution vias 172, the third redistribution lines 173, the fifth redistribution vias 174, the fourth redistribution lines 175, and the sixth redistribution vias 176 may be formed of or include at least one of copper, aluminum, tungsten, nickel, gold, tin, titanium, and an alloy thereof, respectively. In an embodiment, the fourth redistribution vias 172, the third redistribution lines 173, the fifth redistribution vias 174, the fourth redistribution lines 175, and the sixth redistribution vias 176 may be formed by performing a sputtering process, respectively. In another embodiment, the fourth redistribution vias 172, the third redistribution lines 173, the fifth redistribution vias 174, the fourth redistribution lines 175, and the sixth redistribution vias 176 may be formed by performing an electrolytic plating process after forming the seed metal layer, respectively.

FIG. 9 a cross-sectional view showing the step of forming the third through opening 170P on the back side redistribution structure 170.

Referring to FIG. 9, the third through opening 170P is formed on the back side redistribution structure 170. Photoresist (not shown) is additionally deposited on the sixth redistribution vias 176 and the second dielectric material layer 171, and a photoresist pattern is formed by selectively exposing and developing the photoresist. Thereafter, by performing an etching process using the photoresist pattern as a mask, the third through opening 170P is formed on the back side redistribution structure 170.

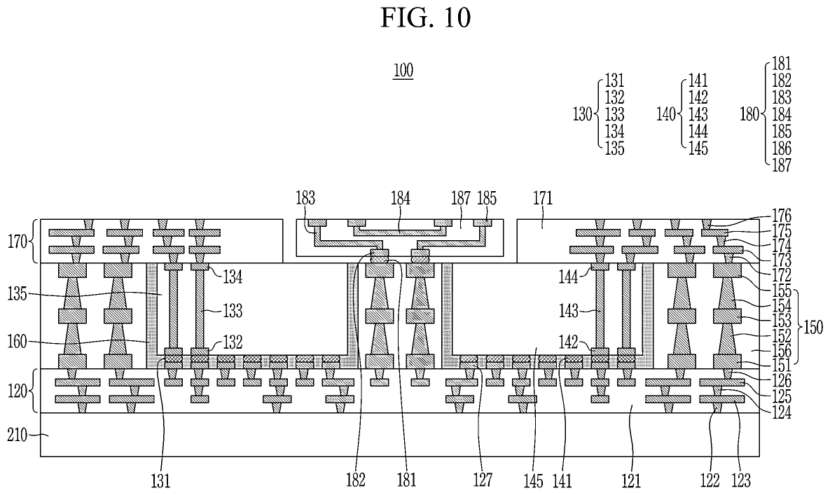

FIG. 10 is a cross-sectional view showing the step of mounting the bridge die 180 within the third through opening 170P of the back side redistribution structure 170.

Referring to FIG. 10, the bridge die 180 is mounted within the third through opening 170P of the back side redistribution structure 170 by flip chip bonding. The connection members 181 of the bridge die 180 are bonded to third wire layers 155 of the substrate 150, and the bridge die 180 and the substrate 150 may be electrically connected to each other. In an embodiment, the connection member 181 may be formed of or include micro-bumps or solder balls.

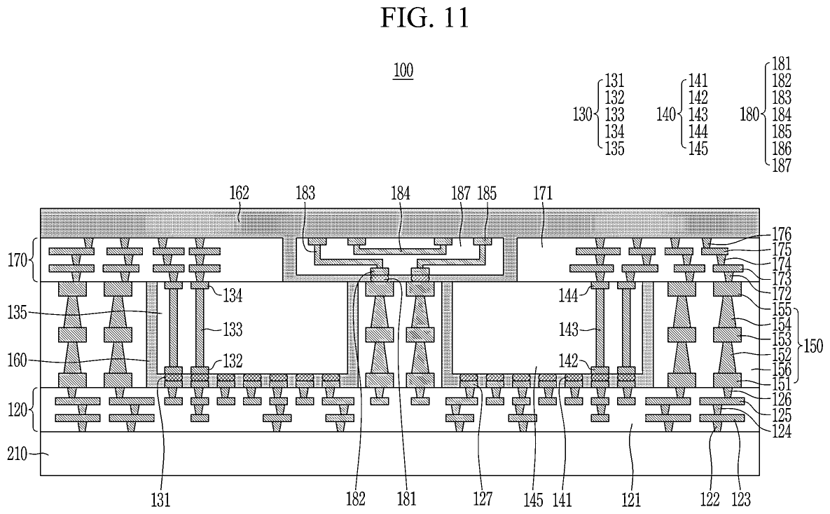

FIG. 11 is a cross-sectional view showing the step of molding the bridge die 180 by the third molding material 162, in the back side redistribution structure 170.

Referring to FIG. 11, within the third through opening 170P of the back side redistribution structure 170, the bridge die 180 is molded (e.g., surrounded) by the third molding material 162. In an embodiment, the process of molding with the third molding material 162 may include a compression molding or transfer molding process. In an embodiment, the third molding material 162 may include an epoxy molding compound EMC.

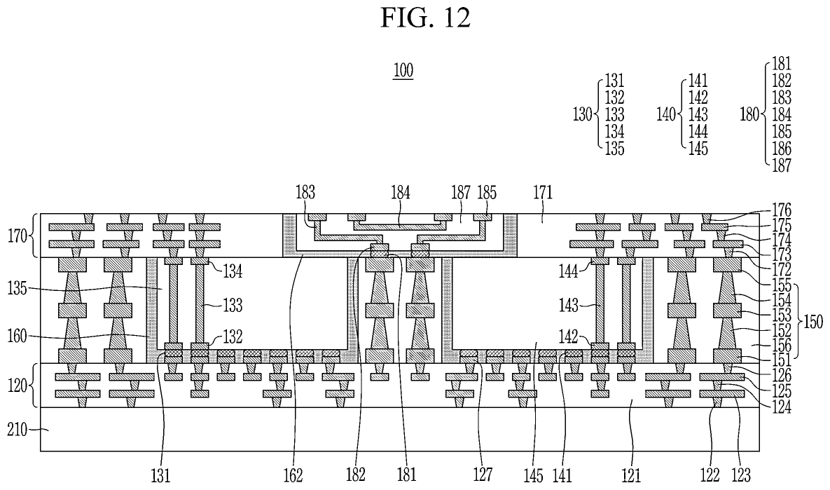

FIG. 12 a cross-sectional view showing the step of planarizing the third molding material 162.

Referring to FIG. 12, chemical mechanical polishing (CMP) may be performed in order to level an upper surface of the third molding material 162. An upper surface of the third molding material 162 is planarized by applying the CMP process. After performing the CMP process, upper surfaces of the back side redistribution structure 170 and the bridge die 180 are exposed.

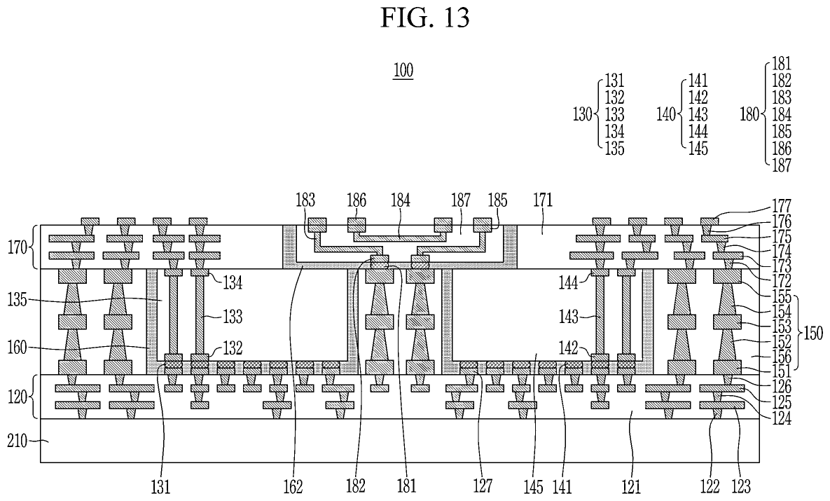

FIG. 13 is a cross-sectional view showing the step of forming the second bonding pads 177 on the back side redistribution structure 170 and forming the third bonding pads 186 on the bridge die 180.

Referring to FIG. 13, the second bonding pads 177 are formed on the back side redistribution structure 170, and the third bonding pads 186 are formed on the bridge die 180. Photoresist (not shown) is additionally deposited on the back side redistribution structure 170 and the bridge die 180, a photoresist pattern including openings is formed by selectively exposing and developing the photoresist, and the second bonding pads 177 and the third bonding pads 186 are formed by filling the openings with a conductive material. In another embodiment, the process of forming the second bonding pads 177 and the third bonding pads 186 may be sequentially performed as separate processes instead of being performed as a single process.

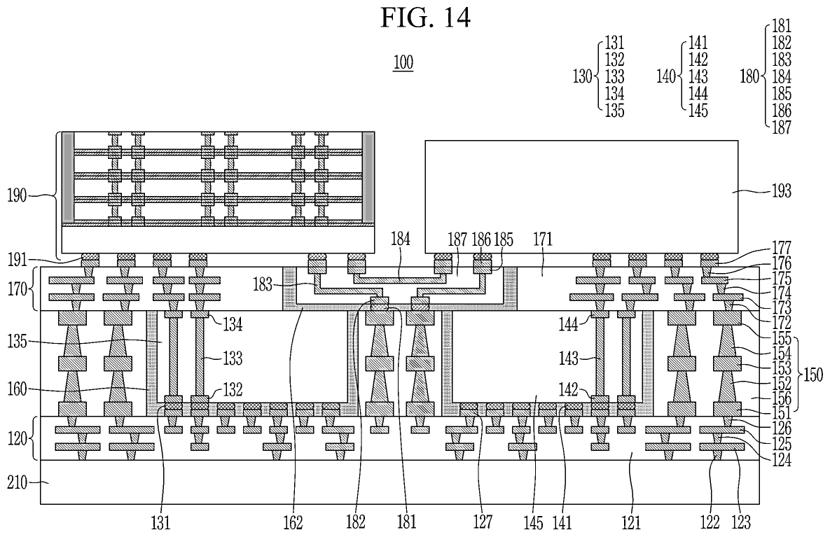

FIG. 14 is a cross-sectional view showing the step of mounting the third semiconductor die 190 and the fourth semiconductor die 193 on the back side redistribution structure 170 and on the bridge die 180.

Referring to FIG. 14, the third semiconductor die 190 and the fourth semiconductor die 193 are mounted on the back side redistribution structure 170, and on the bridge die 180 by flip chip bonding. The third semiconductor die 190 and the fourth semiconductor die 193 are disposed side by side and at the same level. As at least one of the third connection members 191 of the third semiconductor die 190 is bonded to the second bonding pads 177 of the back side redistribution structure 170, the third semiconductor die 190 and the back side redistribution structure 170 are electrically connected to each other, and as the remaining third connection members 191 of the third semiconductor die 190 are bonded to the third bonding pads 186 of the bridge die 180, the third semiconductor die 190 and the bridge die 180 are electrically connected to each other. As at least one of the fourth connection members 194 of the fourth semiconductor die 193 is bonded to the second bonding pads 177 of the back side redistribution structure 170, the fourth semiconductor die 193 and the back side redistribution structure 170 are electrically connected to each other, and as the remaining fourth connection members 194 of the fourth semiconductor die 193 are bonded to the third bonding pads 186 of the bridge die 180, the fourth semiconductor die 193 and the bridge die 180 are electrically connected to each other.

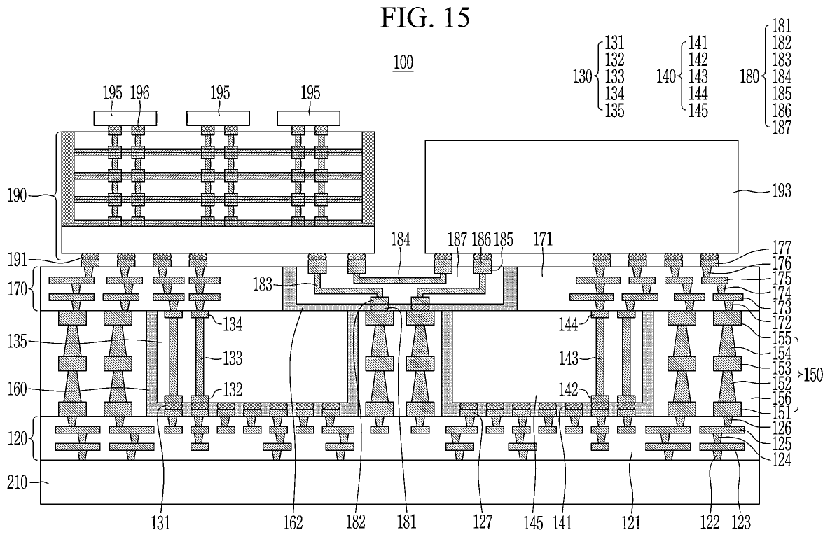

FIG. 15 a cross-sectional view showing the step of mounting the one or more surface-mount devices (SMD) 195 on the third semiconductor die 190.

Referring to FIG. 15, the one or more surface-mount devices (SMD) 195 is mounted on the third semiconductor die 190 by flip chip bonding.

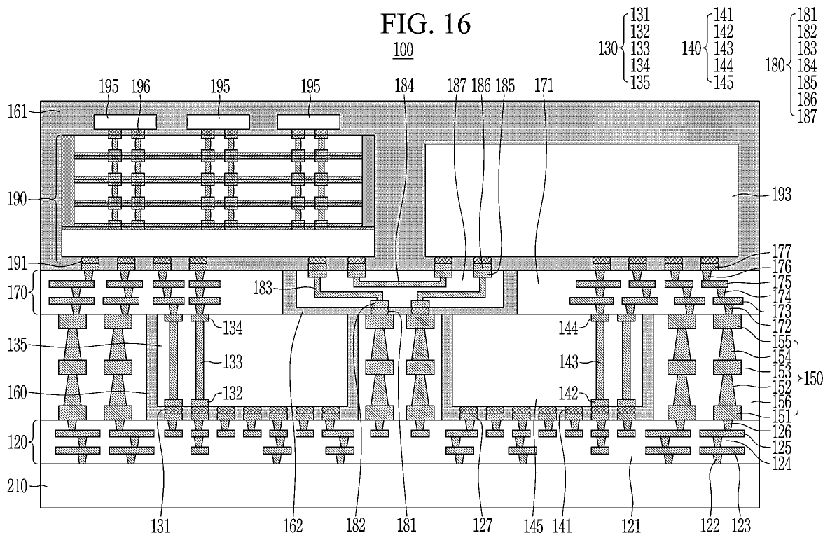

FIG. 16 is a cross-sectional view showing the step of molding the third semiconductor die 190 and the fourth semiconductor die 193 by the second molding material 161, on the back side redistribution structure 170.

Referring to FIG. 16, on the back side redistribution structure 170, the third semiconductor die 190 and the fourth semiconductor die 193 are molded (e.g., surrounded) by the second molding material 161. In an embodiment, the process of molding with the second molding material 161 may include a compression molding or transfer molding process. In an embodiment, the second molding material 161 may include an epoxy molding compound EMC.

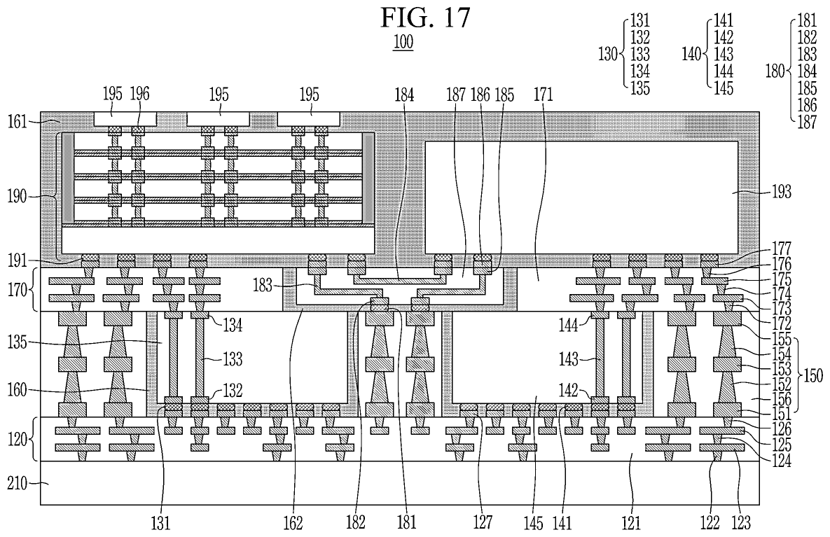

FIG. 17 a cross-sectional view showing the step of planarizing the second molding material 161.

Referring to FIG. 17, chemical mechanical polishing (CMP) may be performed in order to level an upper surface of the second molding material 161. p An upper surface of the second molding material 161 may be planarized by applying the CMP process. After performing the CMP process, an upper surface of the one or more surface-mount devices (SMD) 195 are exposed.

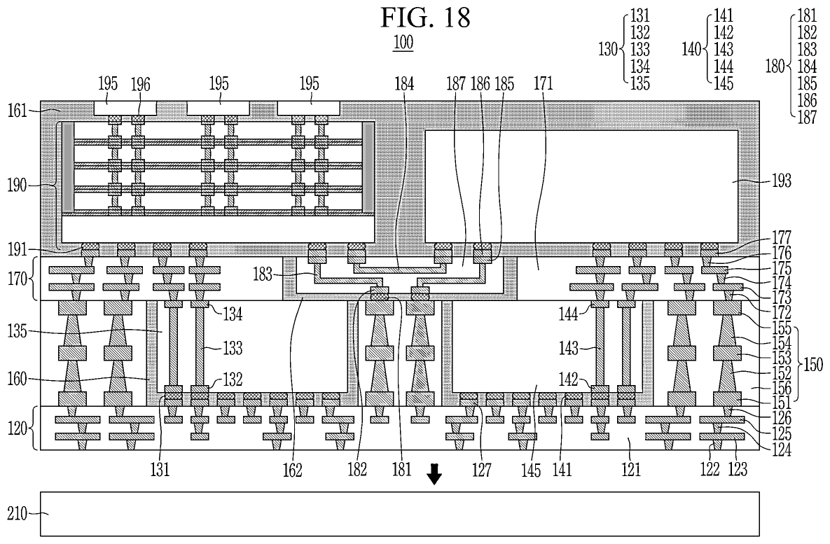

FIG. 18 is a cross-sectional view showing the step of removing the carrier 210 from the front side redistribution structure 120.

Referring to FIG. 18, the carrier 210 may be removed from a bottom surface of the front side redistribution structure 120.

Thereafter, as shown in FIG. 1, the external connection structure 110 may be formed on the bottom surface of the front side redistribution structure 120. Referring to FIG. 1, the external connection structure 110 on the front side redistribution structure 120 may be formed. The insulation member 112 may be formed on the bottom surface of the first dielectric material layer 121 of the front side redistribution structure 120, and the conductive pads 111 may be formed under the first redistribution vias 122. In an embodiment, the conductive pad 111 may be formed of or include at least one of copper, nickel, zinc, gold, silver, platinum, palladium, chromium, titanium, and an alloy thereof. In an embodiment, the insulation member 112 may be formed of or include solder resist. In an embodiment, the external connection member 113 may be formed of or include at least one of tin, silver, lead, nickel, copper or an alloy thereof. In an embodiment, the conductive pad 111 may be formed by performing a sputtering process or an electrolytic plating process after forming a seed metal layer. In an embodiment, the insulation member 112 may be formed by a CVD, ALD, or PECVD process.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the disclosure.

What is claimed is:

1. A semiconductor package, comprising:
a first redistribution structure;
a first semiconductor die on the first redistribution structure;
a second semiconductor die on the first redistribution structure and side-by-side with the first semiconductor die;
a substrate on the first redistribution structure and surrounding each of the first semiconductor die and the second semiconductor die;
a bridge die on the substrate;
a second redistribution structure on the substrate and around the bridge die;
a third semiconductor die on the second redistribution structure and on the bridge die; and
a fourth semiconductor die on the second redistribution structure and on the bridge die.

2. The semiconductor package of claim 1, wherein:
each of the first semiconductor die and the second semiconductor die comprises a plurality of through-silicon vias; and
the plurality of through-silicon vias electrically connects the first redistribution structure to the second redistribution structure.

3. The semiconductor package of claim 1, wherein:
the substrate comprises a first through opening and a second through opening;
the first semiconductor die is disposed within the first through opening; and
the second semiconductor die is disposed within the second through opening.

4. The semiconductor package of claim 1, wherein:
the second redistribution structure comprises a third through opening; and
the bridge die is disposed within the third through opening.

5. The semiconductor package of claim 1, wherein the bridge die comprises a plurality of first wire lines that electrically connect the third semiconductor die to the substrate and the fourth semiconductor die to the substrate.

6. The semiconductor package of claim 1, wherein the bridge die comprises a plurality of second wire lines that electrically connect the third semiconductor die to the fourth semiconductor die.

7. The semiconductor package of claim 1, wherein:
the third semiconductor die comprises plurality of connection members; and
at least one of the plurality of connection members is connected to the second redistribution structure, and the remaining connection members of the plurality of connection members are connected to the bridge die.

8. The semiconductor package of claim 1, wherein:
the fourth semiconductor die comprises plurality of connection members; and
at least one of the plurality of connection members is connected to the second redistribution structure, and the remaining connection members of the plurality of connection members are connected to the bridge die.

9. A semiconductor package, comprising:
a first redistribution structure;
a first semiconductor die on the first redistribution structure;
a second semiconductor die on the first redistribution structure and side-by-side with the first semiconductor die;
a substrate on the first redistribution structure and surrounding each of the first semiconductor die and the second semiconductor die;
a first molding material surrounding the first semiconductor die and the second semiconductor die, on the first redistribution structure;
a bridge die on the substrate;
a second redistribution structure on the substrate and around the bridge die;
a third semiconductor die on the second redistribution structure and on the bridge die;
a fourth semiconductor die on the second redistribution structure and on the bridge die;
a second molding material surrounding the third semiconductor die and the fourth semiconductor die, on the second redistribution structure; and
a surface-mount device (SMD) disposed on the third semiconductor die.

10. The semiconductor package of claim 9, wherein the surface-mount device comprises an integrated stack capacitor (ISC).

11. The semiconductor package of claim 9, wherein the first semiconductor die comprises an application processor (AP).

12. The semiconductor package of claim 9, wherein the second semiconductor die comprises a communication processor (CP).

13. The semiconductor package of claim 9, wherein the substrate comprises an embedded trace substrate (ETS).

14. The semiconductor package of claim 9, wherein the bridge die comprises a silicon bridge die.

15. The semiconductor package of claim 9, wherein the third semiconductor die comprises a high bandwidth memory (HBM).

16. The semiconductor package of claim 9, wherein the fourth semiconductor die comprises a radio frequency IC (RFIC) chip, a display driver IC (DDI) chip, a sensor chip, or a power management IC (PMIC) chip.

17. A manufacturing method of a semiconductor package, the manufacturing method comprising:
forming a first redistribution structure;
bonding a substrate comprising a first through opening and a second through opening on the first redistribution structure;
mounting a first semiconductor die on the first redistribution structure and within the first through opening, and mounting a second semiconductor die on the first redistribution structure and within the second through opening;
forming a second redistribution structure on the first semiconductor die, the second semiconductor die, and the substrate;
mounting a bridge die within the second redistribution structure; and
mounting a third semiconductor die and a fourth semiconductor die on the second redistribution structure and on the bridge die.

18. The manufacturing method of claim 17, wherein, the substrate is bonded to the first redistribution structure by a thermal compression.

19. The manufacturing method of claim 17, wherein the forming the second redistribution structure comprises forming a third through opening in the second redistribution structure.

20. The manufacturing method of claim 17, further comprising mounting a surface-mount device on the third semiconductor die.
